(19) United States
(12) Patent Application Publication
(10) Pub. No.: US 2009/0146700 A1
(43) Pub. Date: Jun. 11, 2009

(54) DUTY RATIO CORRECTION CIRCUIT

(75) Inventors: Yong Ju Kim, Ichon (KR); Kun Woo Park, Ichon (KR); Kyung Hoon Kim, Ichon (KR); Hee Woong Song, Ichon (KR); Ic Su Oh, Ichon (KR); Hyung Soo Kim, Ichon (KR); Tae Jin Hwang, Ichon (KR); Hae Rang Choi, Ichon (KR); Ji Wang Lee, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR, INC., Ichon (KR)

(21) Appl. No.: 12/178,475

(22) Filed: Jul. 23, 2008

(30) Foreign Application Priority Data
Dec. 7, 2007 (KR) 10-2007-0126669

(51) Int. Cl. H03L 7/00

(52) U.S. Cl. 327/144

(57) ABSTRACT

A duty ratio correction circuit including a reference clock generation block configured to generate first and second reference clocks that synchronize with rising and falling edges of an external clock and have a primarily corrected duty ratio, and a duty ratio adjustment block for generating first and second internal clocks in response to the first and second reference clocks, and secondarily correcting a duty ratio of the first and second reference clocks by adjusting phases of the first and second reference clocks by means of plural digital control signals generated according to phase difference between the first and second internal clocks.

### CROSS-REFERENCES TO RELATED APPLICATION

The present application claims priority under 35 U.S.C. 119(a) to Korean application number 10-2007-0126669, filed on Dec. 7, 2007, in the Korean Intellectual Property Office, the disclosure of which is incorporated herein in its entirety by reference, as if set forth in full.

### BACKGROUND

1. Technical Field

The disclosure herein relates to a duty ratio correction circuit and, more particularly, to a duty ratio correction circuit capable of controlling a duty ratio of a clock signal.

2. Related Art

In general, a conventional DDR (double data rate) circuit can continuously output two data elements per one clock period by performing input and output operations using rising and falling edges of a clock. Thus, a ratio (i.e. duty ratio) of a low level pulse width interval to a high level pulse width interval must be maintained at 50% (50:50).

Meanwhile, accurate timing of data output from the DDR circuit is provided to a CPU (central processing unit) or a memory controller located outside of a semiconductor memory device. Thus, the CPU or the memory controller uses a data strobe signal serving as a reference for data input/output such that a time skew between semiconductor memory devices can be minimized. The data strobe signal is generated using a rising clock, which is generated in synchronization with a rising edge of an external clock, and a falling clock generated in synchronization with a falling edge of the external clock. Accordingly, a duty ratio of such a data strobe signal must be maintained at 50% (50:50).

If an error of the duty ratio of the data strobe signal is increased, a design margin is reduced in designing a circuit. Thus, a clock duty ratio of 50% must be maintained in order to ensure sufficient input/output data valid window in a system.

### SUMMARY

A duty ratio correction circuit having an improved duty ratio of a clock is described herein.

According to one aspect, a duty ratio correction circuit can include a reference clock generation block configured to generate first and second reference clocks that synchronize with rising and falling edges of an external clock and have a primarily corrected duty ratio, and a duty ratio adjustment block configured to generate first and second internal clocks in response to the first and second reference clocks, and secondarily correcting a duty ratio of the first and second reference clocks by adjusting phases of the first and second reference clocks by means of plural digital control signals generated according to phase difference between the first and second internal clocks.

In another aspect, a duty ratio correction circuit can include a reference clock generation block configured to generate first and second reference clocks, which have a phase difference of 180° there between, from an external clock, and a duty ratio adjustment block configured to generate first and second internal clocks in response to the first and second reference clocks, in which the duty ratio adjustment block can be controlled by a plurality of digital control signals generated according to a comparison result of high level intervals of the first and second reference clocks to correct a duty ratio of the first and second reference clocks by mixing phases of the first and second reference clocks.

In still another aspect, a duty ratio correction circuit can include a phase adjustment block configured to generate first and second internal clocks by receiving first and second reference clocks generated in synchronization with rising and falling edges of an external clock; a multiplexer configured to receive the first and second internal clocks to selectively provide the first and second internal clocks, and a phase adjustment block controller configured to generate plural control signals in response to difference between phases of the first and second internal clocks output from the multiplexer, and adjusting the phases of the first and second internal clocks in response to the control signals.

These and other features, aspects, and embodiments are described below in the section entitled “Detailed Description.”

### BRIEF DESCRIPTION OF THE DRAWINGS

Features, aspects, and embodiments are described in conjunction with the attached drawings, in which:

FIG. 1 is a block diagram of a duty ratio correction circuit according to one embodiment;

FIG. 2 is a detailed block diagram of a duty ratio correction that can be included in the circuit illustrated in FIG. 1;

FIG. 3 is a block diagram of a phase adjustment block controller that can be included in the circuit illustrated in of FIG. 2;

FIG. 4 is a circuit diagram of a duty detector that can be included in the circuit illustrated in FIG. 3;

FIG. 5 is a circuit diagram of a code generator that can be included in the circuit illustrated in FIG. 3;

FIG. 6 is a block diagram schematically showing a phase adjustment block that can be included in the circuit illustrated in FIG. 2;

FIG. 7 is a block diagram of a first phase adjustment unit that can be included in the circuit illustrated in FIG. 6; and

FIG. 8 is a circuit diagram of a first clock receiving unit that can be included in the circuit illustrated in FIG. 7.

### DETAILED DESCRIPTION OF THE PREFERRED EMBODIMENTS

In Accordance with the embodiments described herein, internal clocks having a corrected duty ratio can be generated from a reference clock. When generating the internal clocks by receiving the reference clock, a phase difference between the internal clocks can be detected for a predetermined cycle, so that distortion in a duty ratio of the reference clock can be estimated. Thus, a phase of the reference clock can be adjusted such that the distorted duty ratio of the reference clock can be compensated. This can be achieved by generating a digital code signal from the phase difference detected between the internal clocks. In brief, the duty ratio of the reference clock is corrected in a simple code generation scheme, so that the duty ratio of the internal clock can also be corrected. Thus, an internal clock signal having a corrected duty ratio is generated, so that a duty ratio of a data strobe signal serving as a reference for data output can also be improved. Consequently, a sufficient data valid window can be ensured.

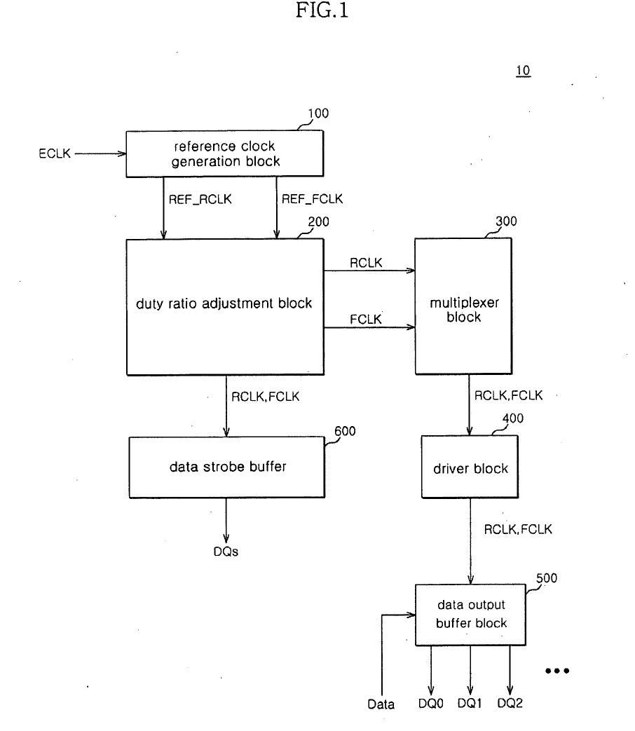

It will be clear that the embodiments described herein may be practiced without some or all of these specific details. In other instances, well known process operations have not been described in detail in order not to unnecessarily obscure the description of these embodiments.FIG. 1 is a block diagram of a duty ratio correction circuit according to one embodiment described herein. Referring to FIG. 1, the duty ratio correction circuit 10 can include a reference clock generation block 100, a duty ratio adjustment block 200, a multiplexer block 300, a driver block 400, a data output buffer block 500, and a data strobe buffer 600.

The reference clock generation block 100 can receive an external clock “ECLK” and generate a reference rising clock “REF_RCLK” as a first reference clock and a reference falling clock “REF_FCLK” as a second reference clock in synchronization with rising and falling edges of the external clock “ECLK”. The reference rising clock “REF_RCLK” and the reference falling clock “REF_FCLK” are clock signals that maintain a phase difference of 180° there between.

The duty ratio adjustment block 200 according to one embodiment described herein receives the reference rising clock “REF_RCLK” and the reference falling clock “REF_FCLK” to generate a rising clock “RCLK”, which is a first internal clock signal, and a falling clock “FCLK”, which is a second internal clock signal. The rising clock “RCLK” and the falling clock “FCLK” are used as internal clocks. In more detail, the duty ratio adjustment block 200 can detect a phase difference between the rising clock “RCLK” and the falling clock “FCLK”, which are generated from the reference rising clock “REF_RCLK” and the reference falling clock “REF_FCLK”, respectively. If a phase difference is detected, the duty ratio adjustment block 200 can adjust the phases of the reference rising clock “REF_RCLK” and the reference falling clock “REF_FCLK”, which serve as source signals of the rising clock “RCLK” and the falling clock “FCLK”. Thus, the rising clock “RCLK” and the falling clock “FCLK”, which have an adjusted duty ratio, can be generated. A detailed description will be described later.

The multiplexer block 300 can receive the rising clock “RCLK” and the falling clock “FCLK”, which have an adjusted duty ratio, from the duty ratio adjustment block 200 and selectively provides the rising clock “RCLK” and the falling clock “FCLK”, which are used for an internal circuit.

The driver block 400 can receive the rising clock “RCLK” and the falling clock “FCLK”, which are selectively provided from the multiplexer block 300, to provide the rising clock “RCLK” and the falling clock “FCLK” to the data output buffer block 500.

Then, the data output buffer block 500 can synchronize the data with the rising clock “RCLK” and the falling clock “FCLK” and output the synchronized data to data input/output pins DQ0 to DQ2.

The data strobe buffer 600 can generate a data strobe signal DQS having an adjusted duty ratio by using the rising clock “RCLK” and the falling clock FCLK, which can have adjusted duty ratios.

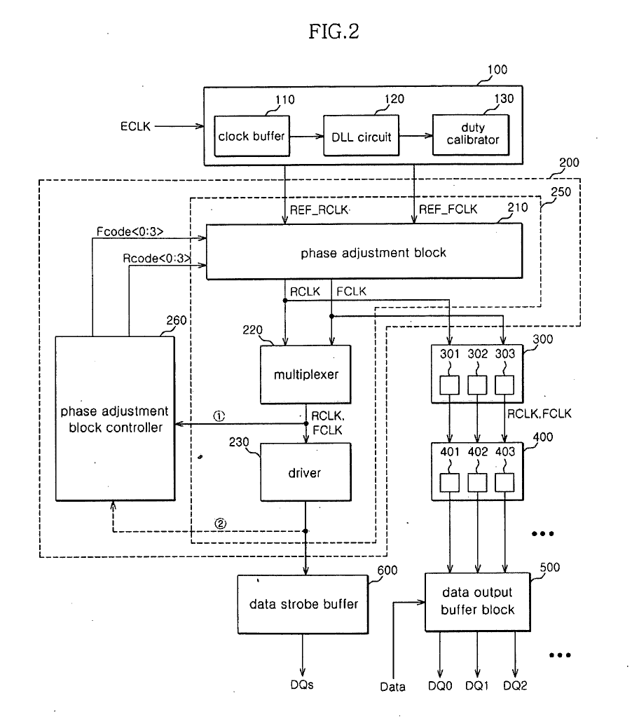

FIG. 2 is a detailed block diagram of the duty ratio correction circuit of FIG. 1. Referring to FIG. 2, the reference clock generation block 100 can include a clock buffer 110, a DLL circuit 120 and a duty calibrator 130.

The clock buffer 110 can receive the external clock “ECLK” to buffer the external clock “ECLK” in order to generate the internal clock signal. The buffered clock signal is transferred to the DLL circuit 120. Although not shown in detail in FIG. 2, the DLL circuit 120 can compare the buffered clock with a feedback clock to detect the phase difference, thereby minimizing clock skew. In one embodiment, the DLL circuit 120 can be used. However, a PLL circuit can also be used according to the construction or purpose of a semiconductor integrated circuit. Further, a loop operation of a predetermined cycle, e.g. several hundreds of cycles, can be performed until a delay-locked clock signal is generated.

The reference clock generation block 100 can include the typical duty calibrator 130 that can generate the reference rising clock “REF_RCLK” and the reference falling clock “REF_FCLK”, which have a corrected duty ratio, from the delay-locked clock signal. Such a duty calibrator 130 can minimize a duty error between the reference rising clock “REF_RCLK” and the reference falling clock “REF_FCLK”, and may be provided at an input terminal of the DLL circuit 120 according to the construction of the semiconductor integrated circuit. Since the duty calibrator 130 can be a conventional duty calibrator properly positioned in the reference clock generation block 100, a detailed description is omitted.

The duty ratio adjustment block 200, according to one embodiment described herein, can include an internal clock signal generator 250 and a phase adjustment block controller 260. The internal clock signal generator 250 can include a phase adjustment block 210, a multiplexer 220, and a driver 230.

The phase adjustment block 210 can receive the reference rising clock “REF_RCLK” and the reference falling clock “REF_FCLK” and generate the rising clock “RCLK”, which is the first internal clock signal, and the falling clock “FCLK”, which is the second internal clock signal. At this time, the phase adjustment block 210 can generate the rising clock “RCLK” and the falling clock “FCLK”, which have an adjusted duty ratio, under the control of the phase adjustment block controller 260.

The multiplexer 220 receives the rising clock “RCLK” and the falling clock “FCLK” to selectively provide the rising clock “RCLK” and the falling clock “FCLK”. For example, such a multiplexer 220 may include a (2:1) multiplexer. The rising clock “RCLK” and the falling clock “FCLK”, which are selectively output, are provided to the phase adjustment block controller 260 and the driver 230.

The phase adjustment block controller 260, according to one embodiment described herein, can detect a phase difference between the rising clock “RCLK” and the falling clock “FCLK” in a high level interval. Then the phase adjustment block controller 260 can generate code signals (“Rcode<0:3>” and “Fcode<0:3>”) which can control the rising and falling clocks, and which are plural control code signals, based on the detected phase difference. Such code signals (“Rcode<0:3>” and “Fcode<0:3>”) can be digital signals that control the phases of the reference rising clock “REF_RCLK” and the reference falling clock “REF_FCLK” of the phase adjustment block 210. The phase adjustment block 210 can adjust the high level pulse width intervals or the low level pulse width intervals of the reference rising clock “REF_RCLK” and the reference falling clock “REF_FCLK” by using the code signals (“Rcode<0:3>” and “Fcode<0:3>”), thereby improving the duty ratio.

In other words, the phase difference between the rising clock “RCLK” and the falling clock “FCLK” in the high level interval may be caused by the duty ratio error between the reference rising clock “REF_RCLK” and the reference falling clock “REF_FCLK”. Thus, the phase difference between the rising clock “RCLK” and the falling clock “FCLK” in the high level interval is detected, and then the code signals (“Rcode<0:3>” and “Fcode<0:3>”) can be used to compensate for the phase difference. The phases of the reference rising clock “REF_RCLK” and the reference falling clock “REF_FCLK” are adjusted using such code signals (“Rcode<0:3>” and “Fcode<0:3>”), so that the duty ratio of the rising clock “RCLK” and the falling clock “FCLK” can be improved.

A conventional semiconductor integrated circuit can generate the rising clock “RCLK” and the falling clock “FCLK” by using the reference rising clock “REF_RCLK” and the reference falling clock “REF_FCLK” provided through the duty calibrator 130. However, since the data output buffer block 500 or the data strobe buffer 600 is provided, distortion of the duty ratio may be caused by physical structure and position, a process problem or device mismatch and the like. The duty ratio distortion of an internal clock may be caused by path and topology of each circuit using the internal clock generated from the DLL circuit.

However, according to one embodiment described herein, the phase adjustment block controller 260 can detect and correct an error of the duty ratio between the rising clock “RCLK” and the falling clock “FCLK”.

According to one embodiment described herein, as described above, the phase adjustment block controller 260 can detect the phase difference between the rising clock “RCLK” and the falling clock “FCLK”, which are output through the multiplexer 220, to generate the code signals for controlling phase adjustment. Then, the phase adjustment block controller 260 can adjust the phases of the reference rising clock “REF_RCLK” and the reference falling clock “REF_FCLK” in response to such code signals, so that the duty ratio of the rising clock “RCLK” and the falling clock “FCLK” can be improved. In addition, the phase adjustment block controller 260 can detect the phase difference between the rising clock “RCLK” and the falling clock “FCLK”, which are output via the driver 230, so that the duty ratio of the rising clock “RCLK” and the falling clock “FCLK” can also be improved.

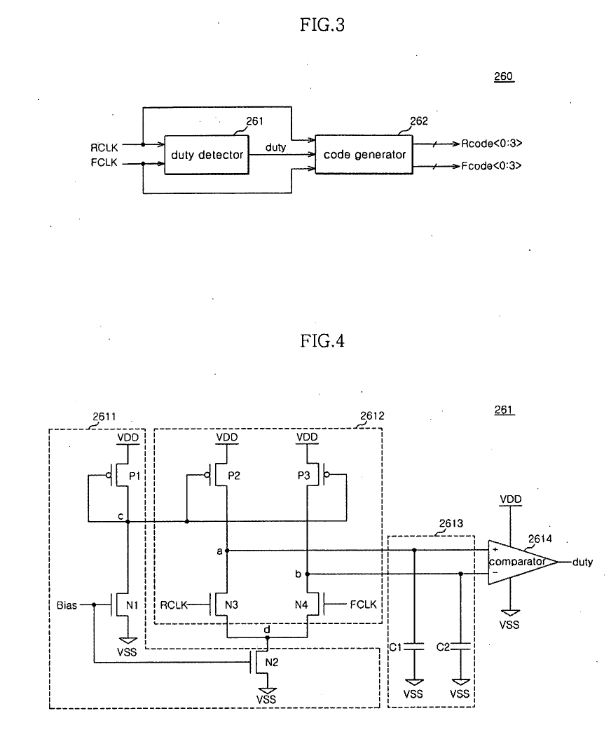

The duty ratio can be improved by performing the duty ratio correction operation using the duty ratio adjustment block 200 during an interval in which loops are properly delayed by the DLL circuit 120. The duty ratio adjustment block 200 will be described in detail with reference to FIG. 3.

The multiplexer block 300 can include a plurality of multiplexers 301 to 303. Such multiplexers 301 to 303 selectively output the rising clock “RCLK” and the falling clock “FCLK” as described above. The driver block 400 can include a plurality of driver units 401 to 403 corresponding to the multiplexers 301 to 303. The multiplexers 301 to 303 and the driver units 401 to 403 may correspond to the input/output pins DQ0 to DQ2 connected with the data output buffer block 500. Consequently, data can be output in response to the rising clock “RCLK” and the falling clock “FCLK”, which have an adjusted duty ratio.

FIG. 3 is one example of a block diagram of a phase adjustment block controller 260. Referring to FIG. 3, the phase adjustment block controller 260 can include a duty detector 261 and a code generator 262.

The duty detector 261 can receive the rising clock “RCLK” and the falling clock “FCLK” to generate a duty signal. Such duty detector 261 detects voltage by using difference in the amount of electric charges that respond to high level intervals of the rising clock “RCLK” and the falling clock “FCLK”. If the rising clock “RCLK” has a high level interval wider than that of the falling clock “FCLK”, the duty detector 261 can provide a duty signal of a high level (first level). However, if the rising clock “RCLK” has a high level interval narrower than that of the falling clock “FCLK”, the duty detector 261 can provide a duty signal of a low level (second level).

The code generator 262 can generate the code signals (“Rcode<0:3>” and “Fcode<0:3>”) for controlling the rising and falling clocks, respectively, in response to the levels of the duty signal. The code signals (“Rcode<0:3>” and “Fcode<0:3>”) are 4-bit digital code signals, respectively however the scope of the embodiments described herein is not limited thereto. Since the code signals (“Rcode<0:3>” and “Fcode<0:3>”) are digital signals for adjusting the high level intervals or the low level intervals of the reference rising clock “REF_RCLK” and the reference falling clock “REF_FCLK”, the number of codes may vary as the clock signal to be controlled is finely adjusted.

FIG. 4 is a detailed circuit diagram of the duty detector 261 of FIG. 3. Referring to FIG. 4, the duty detector 261 can include a controller 2611, a differential amplifier 2612, a signal storage unit 2613 and a comparator 2614. The controller 2611 can control the activation of the duty detector 261 in response to a bias signal. Controller 2611 can include first and second NMOS transistors N1 and N2, and a first PMOS transistor P1.

The first NMOS transistor N1 can include a gate terminal for receiving the bias signal, a drain terminal connected with a node c, and a source terminal connected with the ground power VSS. The second NMOS transistor N2 can include a gate terminal for receiving the bias signal, a drain terminal connected with a node d, and a source terminal connected with the ground power VSS. The first PMOS transistor P1 can include gate and drain terminals, which can be connected commonly with the node c, and a source terminal that receives external supply power VDD.

The differential amplifier 2612 can detect voltage based on minute current difference between two signals in response to the received rising clock “RCLK” and falling clock “FCLK”. Such a differential amplifier 2612 can include third and fourth NMOS transistors N3 and N4, and second and third PMOS transistors P2 and P3. Gate terminals of the third and fourth NMOS transistors N3 and N4 receive the rising clock “RCLK” and the falling clock “FCLK”, respectively. Source terminals thereof can be commonly connected with the node d, and drain terminals thereof can be connected with nodes a and b, respectively.

The signal storage unit 2613 can accumulate voltage signals, which are output from the differential amplifier 2612, as electric charges. The signal storage unit 2613 can include first and second capacitors C1 and C2. The first capacitor C1 can have one side connected with the node a, and the other side connected with the ground power VSS. The second capacitor C2 can have one side connected with the node b, and the other side connected with the ground power VSS. The comparator 2614 can generates a duty signal by comparing difference in voltage output from the signal storage unit 2613.

Hereinafter, an operation of the duty detector 261 will be described with reference to FIG. 4. The first and second NMOS transistors N1 and N2 can be turned on by receiving the activated bias signal, so that the node c is at a low level. Thus, the operation of the differential amplifier 2612 can be activated. In detail, the second and third PMOS transistors P2 and P3 are turned on, and minute voltage difference is generated in the nodes (a and b) according to widths of the high level intervals of the received rising clock “RCLK” and falling clock “FCLK”. At this time, the first and second capacitors C1 and C2 have the same capacitance. Thus, difference in the amount of electric charges stored in the first and second capacitors C1 and C2 is caused by the minute voltage difference in the nodes (a and b). In detail, a larger amount of electric charges are accumulated in the first capacitor C1 or the second capacitor C2 by the rising clock “RCLK” or the falling clock “FCLK” having a wider high level interval. Thus, as shown by Equation 1 below, a voltage signal of an input terminal of the comparator 2614 has a higher level corresponding to one of the rising clock “RCLK” and the falling clock “FCLK”, which has a wider high level interval.

Q=CV Equation 1:

In Equation 1, Q denotes an amount of electric charge, C denotes capacitance, and V denotes voltage.

Accordingly, the comparator 2614 can detect and determine phase differences between the high level intervals of the rising clock “RCLK” and the falling clock “FCLK” based on the amount of electric charges stored in the first and second capacitors C1 and C2.

Hereinafter, a case will be described, in which the rising clock “RCLK” has a high level pulse width interval wider than that of the falling clock “FCLK”. Differences in the amount of electric charges is stored in the signal storage unit 2613. Such differences are caused by a difference between voltage for the high level pulse width interval of the rising clock “RCLK” and voltage for the high level pulse width interval of the falling clock “FCLK”. Since a larger amount of electric charges are stored in the first capacitor C1 of the signal storage unit 2613, the comparator 2614 detects the difference in the amount of electric charges stored in the first and second capacitors C1 and C2, thereby outputting a duty signal at a high level (first level). In detail, the duty signal at a high level represents that the duty ratio of the rising clock “RCLK” exceeds 50%, and the duty ratio of the falling clock “FCLK” is smaller than 50%. Thus, the duty signal at a high level is used for narrowing the high level pulse width interval of the reference rising clock “REF_RCLK”.

Hereinafter, a case will be described, in which the falling clock “FCLK” has a high level pulse width interval wider than that of the rising clock “RCLK”. Difference in the amount of electric charge is stored in the signal storage unit 2613. Such difference is caused by difference between voltage for the high level pulse width interval of the rising clock “RCLK” and voltage for the high level pulse width interval of the falling clock “FCLK”. Since a larger amount of electric charges are stored in the second capacitor C2 of the signal storage unit 2613, the comparator 2614 detects the difference in the amount of electric charges stored in the first and second capacitors C1 and C2, thereby outputting a duty signal at a low level (second level). In detail, the duty signal at a low level represents that the duty ratio of the rising clock “RCLK” is smaller than 50% and that the duty ratio of the falling clock “FCLK” is greater than 50%. Thus, the duty signal at a low level is used for further narrowing the high level pulse width interval of the falling clock “FCLK”.

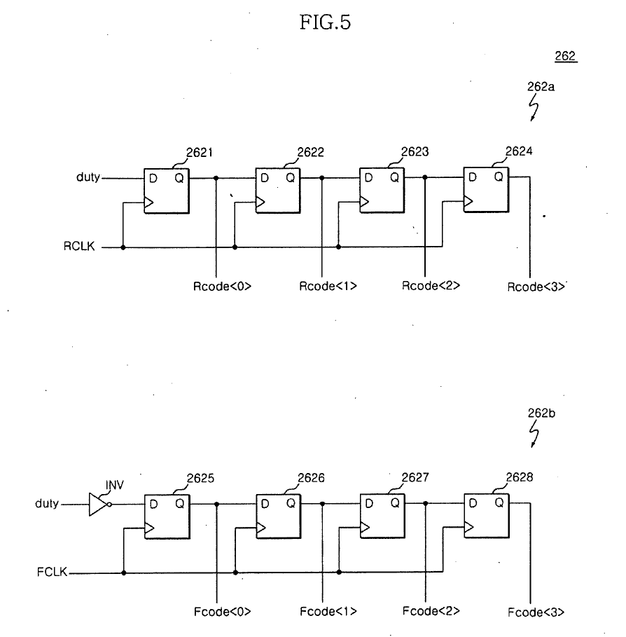

FIG. 5 is a circuit diagram of a code generator 262 as illustrated in FIG. 3. Referring to FIG. 5, the code generator 262 can include a first code group generator 262a and a second code group generator 262b. The first code group generator 262a can generate the code signals (“Rcode<0:3>”) for controlling the rising clock in response to the duty signal. The second code group generator 262b can generate the code signals (“Fcode<0:3>”) for controlling the falling clock in response to the duty signal.

First, the first code group generator 262a can sequentially generate the code signals (“Rcode<0:3>”) in response to the received duty signal. The first code group generator 262a may include a shift register in order to generate a plurality of code signals (“Rcode<0:3>”) for controlling the rising clock. In the embodiment, the first code group generator 262a includes a plurality of D flip-flop devices 2621 to 2624. However, the scope of the embodiment is not limited thereto. In detail, the first code group generator 262a has only to generate plural digital code signals in response to the received duty signal. For example, the first code group generator 262a may include a typical FSM (finite state machine) having a count array.

Hereinafter, an operation of the first code group generator 262a will be described. The first code group generator 262a can sequentially generate a plurality of sequentially shifted code signals (“Rcode<0:3>”) for controlling the rising clock by synchronizing the received duty signal sequentially received with the rising clock “RCLK”. As described above, the DLL circuit (see 120 of FIG. 2) repeats a loop operation until the delay-locked clock signal is generated from the external clock “ECLK”. At this time, the first code group generator 262a can receive the duty signals continuously generated for the loop operation of the DLL circuit (see 120 of FIG. 2), thereby generating the code signals (“Rcode<0:3>”) for controlling the rising clock in synchronization with the rising edge of the rising clock “RCLK” that is continuously generated. In detail, the code signals (“Rcode<0:3>”) may also be continuously changed, which can control the high level pulse width of the rising clock “RCLK” in response to the duty signal that continuously changes while being serialized.

For example, the duty signal is serialized in the form of ‘LHHH’ and then is received in the first flip-flop device 2621. Data, which is received in a terminal D after being triggered at the rising edge of the rising clock “RCLK”, based on the operation principle of the D flip-flop device 2621, is sequentially transferred to the subsequent D flip-flop device 2622. Thus, the duty signal, which is triggered at each rising edge of the rising clock “RCLK”, can be sequentially transferred. Accordingly, a plurality of code signals (“Rcode<0:3>”) for controlling the rising clock can be generated at each rising edge of the rising clock “RCLK”. In other words, the first code signal (“Rcode<0>”) at a low level, the second code signal (“Rcode<1>”) at a high level, the third code signal (“Rcode<2>”) at a high level, and the fourth code signal (“Rcode<3>”) at a high level are generated. In the embodiment, the rising clock “RCLK” is used as a clock signal of the flip-flop device. However, the scope of the embodiment is not limited thereto. The rising clock “RCLK” of the first code group generator 262a is meaningful only when the rising clock “RCLK” is a trigger signal of code signals output from the flip-flop devices 2621 to 2624.

The second code group generator 262b can sequentially generate the code signals (“Fcode<0:3>”) for controlling the falling clock in response to a duty signal inverted by an inverter INV. The second code group generator 262b may include a shift register in order to generate a plurality of code signals (“Fcode<0:3>”) for controlling the falling clock. In one embodiment, the second code group generator 262b can include a plurality of D flip-flop devices 2625 to 2628. Since the second code group generator 262b has the same construction and operation principle as those of the first code group generator 262a, a detailed description thereof will be omitted in order to avoid redundancy, except for difference between the first and second code generators 262a and 262b.

The second code group generator 262b can receive the duty signals that have inverted levels and while being continuously generated, thereby generating a plurality of code signals (“Fcode<0:3>”) for controlling the falling clock in synchronization with the rising edge of the falling clock “FCLK”. In detail, the code signals (“Fcode<0:3>”) may also be continuously changed, which can control the high level pulse width of the falling clock “FCLK” in response to the duty signal that continuously is received while being serialized. At this time, the code signals (“Rcode<0:3>”) have levels inverse to those of the code signals (“Fcode<0:3>”), respectively. Thus, the activated code signals (“Rcode<0:3>”) narrow the high level pulse width of the reference rising clock “REF_RCLK”, and simultaneously the deactivated code signals (“Fcode<0:3>”) widen the high level pulse width of the reference rising clock “REF_RCLK”.

Hereinafter, a process will be described, in which the code signals (“Rcode<0:3>”) and the code signals (“Fcode<0:3>”) control the high level pulse width intervals of the rising clock “RCLK” and the falling clock “FCLK”.

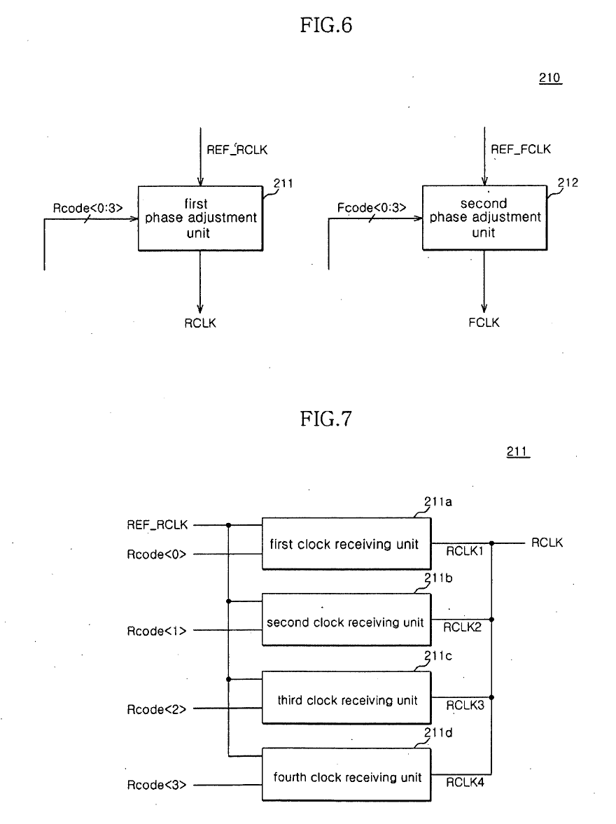

FIG. 6 is a block diagram of the phase adjustment block 210 of FIG. 2. Referring to FIG. 6, the phase adjustment block 210 can include a first phase adjustment unit 211 and a second phase adjustment unit 212. First, the first phase adjustment unit 211 can receive the reference rising clock “REF_RCLK”, and is controlled by the code signals (“Rcode<0:3>”) to generate the rising clock “RCLK” having an adjusted phase.

Further, the second phase adjustment unit 212 can receive the reference falling clock “REF_FCLK”, and can be controlled by the code signals (“Fcode<0:3>”) to generate the falling clock “FCLK” having an adjusted phase.

Since the second phase adjustment unit 212 has the same construction as that of the first phase adjustment unit 211, except for the received signal, the first phase adjustment unit 211 will be described in detail and a description about the second phase adjustment unit 212 will be omitted.

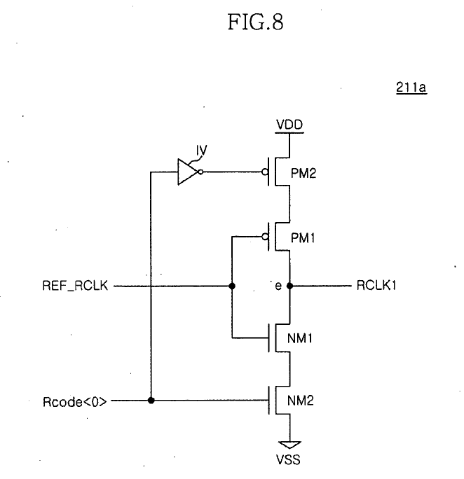

FIG. 7 is a block diagram schematically showing the construction of a first phase adjustment unit 211 which can be included in FIG. 6. FIG. 8 is a circuit diagram of the first clock receiving unit 211a which can be included in FIG. 7. Referring to FIGS. 7 and 8, the first phase adjustment unit 211 can include first to fourth clock receiving units 211a to 211d.

The first to fourth clock receiving units 211a to 211d can receive the reference rising clock “REF_RCLK”, and can be controlled by first to fourth code signals (“RCLK<0:3>”) for controlling the rising clock to output signals “RCLK1” to “RCLK4”, respectively. Then, the signals “RCLK1” to “RCLK4” are combined and generated as the rising clock “RCLK”. Thus, the first to fourth clock receiving unit 211a to 211d may be provided corresponding to the first to fourth code signals (“RCLK<0:3>”).

Hereinafter, each clock receiving unit will be described in detail. Since the first clock receiving unit 211a will be described in detail, a description about the second to fourth clock receiving units 211b to 211d will be omitted in avoid to redundancy. The first clock receiving unit 211a includes first and second NMOS transistors NM1 and NM2, and first and second PMOS transistors PM1 and PM2.

The first NMOS transistor NM1 (pull-down device) is connected with the first PMOS transistor PM1 (pull-up device) to form an inverter. The first NMOS transistor NM1 and the first PMOS transistor PM1 receive the reference rising clock “REF_RCLK” to provide the first rising clock “RCLK1” having a level inverse to that of the reference rising clock “REF_RCLK”. The first NMOS transistor NM1 includes a gate terminal that receives the reference rising clock “REF_RCLK”, a source terminal connected with the second NMOS transistor NM2, and a drain terminal connected with a node e. The first PMOS transistor PM1 includes a gate terminal that receives the reference rising clock “REF_RCLK”, a source terminal connected with the second PMOS transistor PM2, and a drain terminal connected with the node e.

Meanwhile, the second NMOS transistor NM2 and the second PMOS transistor PM2 control the operation of the first clock receiving unit 211a by receiving the first code signal (“RCLK<0>”) for controlling the rising clock, and the first inverted code signal (“RCLK<0>”) for controlling the rising clock, respectively. The second NMOS transistor NM2 can include a gate terminal that receives the first code signal (“RCLK<0>”), a drain terminal connected with the first NMOS transistor NM1, and a drain terminal connected with the ground power VSS. The second PMOS transistor PM2 includes a gate terminal that receives the first code signal (“RCLK<0>”) having an inverted level, a source terminal connected with the first PMOS transistor PM1, and a drain terminal connected with the external supply power VDD.

Hereinafter, a case will be described, in which the first code signal (RCLK<0>) is at a low level as described in FIG. 5. The second NMOS transistor NM2 and the second PMOS transistor PM2 are turned off in response to the first code signal (“RCLK<0>”) at a low level. Thus, the first rising clock “RCLK1” is floated regardless of the level of the received reference rising clock “REF_RCLK”.

If the first code signal (“RCLK<0>”) is at a high level, the second NMOS transistor NM2 and the second PMOS transistor PM2 are turned on. Thus, the first rising clock “RCLK1” is output, which has a level inverse to that of the reference rising clock “REF_RCLK”. In detail, the first rising clock “RCLK1” at a low level is generated in response to the first code signal (“RCLK<0>”) at a high level.

As described above, the first to fourth rising clocks “RCLK1” to “RCLK4” are mixed in response to the first to fourth code signals (“RCLK<0:3>”) received in the first to fourth clock receiving units 211a to 211d, so that the high level pulse width interval of the rising clock “RCLK” is adjusted. In other words, as the first to fourth code signals (“Rcode<0:3>”) at a high level are increased, the pull-down device operates. Thus, the rising clock “RCLK” having a reduced high level pulse width interval can be generated. Similarly, as the first to fourth code signals (“Fcode<0:3>”) at a high level (first level), which are second phase adjustment unit 212, are increased, the pull-down device operates. Thus, the high level pulse width of the falling clock “FCLK” can be reduced.

In one embodiment, the phase adjustment unit can use a mixer. However, the scope of the embodiment is not limited thereto. A delayer having a unit delay time may also be used.

According to one embodiment as described above, the phases of the reference rising clock “REF_RCLK” and the reference falling clock “REF_FCLK”, i.e. the high level pulse width intervals, are adjusted, so that the rising clock “RCLK” and the falling clock “FCLK” having an improved duty ratio can be generated.

Further, the data strobe signal (see DQS of FIG. 2) can be generated using the rising clock and the falling clock “FCLK” having an improved duty ratio. Thus, the duty ratio of the data strobe signal serving as a reference for data output is improved, so that data valid window can be ensured when data is output.

While certain embodiments have been described above, it will be understood that the embodiments described are by way of example only. Accordingly, the apparatus and methods described herein should not be limited based on the described embodiments. Rather, the apparatus and methods described herein should only be limited in light of the claims that follow when taken in conjunction with the above description and accompanying drawings.

What is claimed is:

1. A duty ratio correction circuit comprising:
a reference clock generation block configured to generate first and second reference clocks that synchronize with rising and falling edges of an external clock and have a primarily corrected duty ratio; and
a duty ratio adjustment block couple to the reference clock generation block, the duty ratio adjustment block configured to generate first and second internal clocks in response to the first and second reference clocks, and secondarily correcting a duty ratio of the first and second reference clocks by adjusting phases of the first and second reference clocks via plural digital control signals generated according to a phase difference between the first and second internal clocks.

2. The duty ratio correction circuit of claim 1, wherein the duty ratio adjustment block comprises a phase adjustment block controller and wherein the phase adjustment block controller comprises:
a duty detector configured to provide a duty signal by detecting the phase difference between the first and second internal clocks; and
a code generator coupled to the duty detector, the code generator configured to generate the control signals in response to a level of the duty signal.

3. The duty ratio correction circuit of claim 2, wherein the duty detector is configured to receive the first and second internal clocks and generate the duty signal based on a difference in an amount of electric charges that respond to high level intervals of the first and second internal clocks.

4. The duty ratio correction circuit of claim 2, wherein the duty detector provides the duty signal at a first level when the first internal clock has a high level interval wider than a high level interval of the second internal clock.

5. The duty ratio correction circuit of claim 2, wherein the duty detector provides the duty signal at a second level when the first internal clock has a high level interval narrower than a high level interval of the second internal clock.

6. The duty ratio correction circuit of claim 2, wherein the duty detector includes:
a controller configured to control activation of the duty detector in response to an activation signal;
a differential amplifier coupled to the controller, the differential amplifier configured to receive the first and second internal clocks and output voltage caused by minute current difference under a control of the controller;
a signal storage unit coupled to the differential amplifier, the signal storage until configured to store a voltage output from the differential amplifier, as an electric charge; and
a comparator coupled to the signal storage unit, the comparator configured to generate the duty signal by comparing difference in voltage output from the signal storage unit.

7. The duty ratio correction circuit of claim 2, wherein the code generator comprises:
a first code group generator configured to generate first code signals for controlling a reference clock as the control signals in response to the duty signal; and
a second code group generator configured to generate second code signals for controlling a reference clock as the control signals in response to the duty signal.

8. The duty ratio correction circuit of claim 7, wherein the first and second code group generators comprise plural shift registers corresponding to the first and second code signals, respectively.

9. A duty ratio correction circuit comprising:
a reference clock generation block configured to generate first and second reference clocks, having a phase difference of 180° therebetween, from an external clock; and
a duty ratio adjustment block coupled to the reference clock generation block, the duty ratio adjustment block configured to generate first and second internal clocks in response to the first and second reference clocks, wherein the duty ratio adjustment block is controlled by plural digital control signals generated according to a comparison result of high level intervals of the first and second reference clocks to correct a duty ratio of the first and second reference clocks by mixing phases of the first and second reference clocks.

10. The duty ratio correction circuit of claim 9, wherein the duty ratio adjustment block comprises a phase adjustment block controller and wherein the phase adjustment block controller comprises:
a duty detector configured to provide a duty signal by detecting the phase difference between the first and second internal clocks; and
a code generator coupled to the duty detector, the code generator configured to generate the control signals in response to a level of the duty signal.

11. The duty ratio correction circuit of claim 10, wherein the duty detector is configured to receive the first and second internal clocks to generate the duty signal based on a difference in an amount of electric charges that respond to high level intervals of the first and second internal clocks.

12. The duty ratio correction circuit of claim 10, wherein the duty detector is configured to provide the duty signal at a first or second level in response to the comparison result of the high level intervals of the first and second reference clocks.

13. The duty ratio correction circuit of claim 12, wherein the duty signal at a first level is used to reduce the high level interval of the first internal clock.

14. The duty ratio correction circuit of claim 12, wherein the duty signal at a second level is used to reduce the high level interval of the second internal clock.

15. The duty ratio correction circuit of claim 10, wherein the duty detector comprises:
a controller configured to control activation of the duty detector in response to an activation signal;
a differential amplifier coupled to the controller, the differential amplifier configured to receive the first and second internal clocks to output voltage caused by minute current difference under a control of the controller;
a signal storage unit coupled to the differential amplifier, the signal storage unit configured to store voltage output from the differential amplifier as electric charges; and
a comparator coupled to the signal storage unit, the signal storage unit configured to generate the duty signal by comparing difference in voltage output from the signal storage unit.

16. The duty ratio correction circuit of claim 10, wherein the code generator comprises:
a first code group generator for generating first code signals configured to control a reference clock as the control signals in response to the duty signal; and
a second code group generator for generating second code signals for controlling a reference clock as the control signals in response to the duty signal.

17. The duty ratio correction circuit of claim 16, wherein the first and second code group generators include plural shift registers corresponding to the first and second code signals, respectively.

18. A duty ratio correction circuit comprising:
a phase adjustment block configured to generate first and second internal clocks by receiving first and second reference clocks generated in synchronization with rising and falling edges of an external clock;
a multiplexer coupled to the phase adjustment block, the multiplexer configured to receive the first and second internal clocks to selectively provide the first and second internal clocks; and
a phase adjustment block controller coupled to the multiplexer, the phase adjustment block controller configured to generate plural control signals in response to difference between phases of the first and second internal clocks output from the multiplexer, and adjusting the phases of the first and second internal clocks in response to the control signals.

19. The duty ratio correction circuit of claim 18, wherein the phase adjustment block controller comprises:
a duty detector configured to provide a duty signal by detecting the phase difference between the first and second internal clocks; and
a code generator coupled to the duty detector, the code generator configured to generate the control signals in response to a level of the duty signal.

20. The duty ratio correction circuit of claim 19, wherein the duty detector is configured to receive the first and second internal clocks to generate the duty signal based on difference in an amount of electric charges caused by output voltage driven in response to high level intervals of the first and second internal clocks.

21. The duty ratio correction circuit of claim 19, wherein the duty detector is configured to provide the duty signal at a first level when the first internal clock has a high level interval wider than a high level interval of the second internal clock.

22. The duty ratio correction circuit of claim 19, wherein the duty detector is configured to provide the duty signal at a second level when the first internal clock has a high level interval narrower than a high level interval of the second internal clock.

23. The duty ratio correction circuit of claim 19, wherein the duty detector comprises:
a controller configured to control activation of the duty detector in response to an activation signal;
a differential amplifier coupled to the controller, the differential amplifier configured to receive the first and second internal clocks to output voltage caused by minute current difference under a control of the controller;
a signal storage unit coupled to the differential amplifier, the signal storage unit configured to store a voltage, which is output from the differential amplifier, as electric charges; and
a comparator coupled to the signal storage, the comparator configured to generate the duty signal by comparing difference in voltage output from the signal storage unit.

24. The duty ratio correction circuit of claim 19, wherein the code generator comprises:
a first code group generator configured to generate first code signals for controlling a reference clock as the control signals in response to the duty signal; and
a second code group generator configured to generate second code signals for controlling a reference clock as the control signals in response to the duty signal.

25. The duty ratio correction circuit of claim 24, wherein the first and second code group generators comprise plural shift registers corresponding to the first and second code signals, respectively.
